(19) United States
(12) Patent Application Publication
(10) Pub. No.: US 2015/0380296 A1
(43) Pub. Date: Dec. 31, 2015

(54) CLEANING OF CARBON-BASED CONTAMINANTS IN METAL INTERCONNECTS FOR INTERCONNECT CAPPING APPLICATIONS

(71) Applicant: Lam Research Corporation, Fremont, CA (US)

(72) Inventors: George Andrew Antonelli, Portland, OR (US); Thomas Joseph Knisley, Beaverton, OR (US); Pramod Subramonium, Beaverton, OR (US)

(21) Appl. No.: 14/314,479

(22) Filed: Jun. 25, 2014

(51) Int. Cl. H01L 21/768; C23C 16/02; C23C 16/52

(52) U.S. Cl. CPC H01L 21/7685; C23C 16/52; C23C 16/0227

(57) ABSTRACT

Protective caps residing at an interface between copper lines and dielectric diffusion barrier layers are used to improve various performance characteristics of interconnects. The caps, such as cobalt-containing caps or manganese-containing caps, are selectively deposited onto exposed copper lines in a presence of exposed dielectric using CVD or ALD methods. The deposition of the capping material is affected by the presence of carbon-containing contaminants on the surface of copper, which may lead to poor or uneven growth of the capping layer. A method of removing carbon-containing contaminants from the copper surface prior to deposition of caps involves contacting the substrate containing the exposed copper surface with a silylating agent at a first temperature to form a layer of reacted silylating agent on the copper surface, followed by heating the substrate at a higher temperature to release the reacted silylating agent from the copper surface.

### FIELD OF THE INVENTION

The present invention pertains to methods of forming layers of material on a partially fabricated integrated circuit. Specifically, the invention pertains to methods of cleaning carbon-based contaminants in metal interconnects for interconnect capping applications.

### BACKGROUND OF THE INVENTION

Damascene processing is a method for forming metal lines on integrated circuits. It involves formation of inlaid metal lines in trenches and vias formed in a dielectric layer (inter layer dielectric). Damascene processing is often a preferred method because it requires fewer processing steps than other methods and offers a higher yield. It is also particularly well-suited to metals such as copper that cannot be readily patterned by plasma etching.

In a typical Damascene process, metal is deposited onto a patterned dielectric to fill the vias and trenches formed in the dielectric layer. The resulting metallization layer is typically formed either directly on a layer carrying active devices, or on a lower-lying metallization layer. A thin layer of a dielectric diffusion barrier material, such as silicon carbide or silicon nitride, is deposited between adjacent metallization layers to prevent diffusion of metal into bulk layers of dielectric. In some cases, silicon carbide or silicon nitride dielectric diffusion barrier layer also serves as an etch stop layer during patterning of inter layer dielectric (ILD).

In a typical integrated circuit (IC), several metallization layers are deposited on top of each other forming a stack, where metal-filled vias and trenches serve as IC conducting paths. The conducting paths of one metallization layer are connected to the conducting paths of an underlying or overlying layer by a series of Damascene interconnects.

Fabrication of these interconnects presents several challenges, which become more and more significant as the dimensions of IC device features continue to shrink. For example, adhesion of copper metal to an overlying dielectric diffusion barrier layer is often poor leading to reduced reliability of formed IC devices. Further, aggressive reduction in copper line dimensions leads to an increase in electromigration. In some cases, capping layers are deposited on top of copper to address these problems and to improve reliability of interconnects.

### SUMMARY OF THE INVENTION

One challenging problem encountered during IC fabrication is contamination of metal line surfaces with carbon-containing residue. Presence of such contamination can hinder the deposition of caps on metal lines. For example, when metal-containing caps, such as cobalt-containing caps or manganese-containing caps are deposited by chemical vapor deposition (CVD) or atomic layer deposition (ALD) on a surface contaminated with carbon, low deposition rates, patchy and uneven deposition may result. Further, when metal-containing conductive capping layers are deposited, such capping layers should be deposited selectively on the metal line surface without being deposited on surrounding ILD surfaces. In many instances, presence of carbon-based contaminants on the surface of the metal line reduces selectivity of such deposition.

While contamination with oxide species, such as with copper oxide can be readily removed by treatment of the substrate with reducing agents (e.g., by plasma or thermal treatment in a reducing atmosphere), contamination with carbon-containing species is generally not easily treated. Unexpectedly, a treatment for removing carbon-based contaminants from metal surfaces using a silylating agent, was discovered. The treatment can be used to clean metals, such as copper, cobalt, and nickel (including their alloys) from carbon-based contaminants (such as contaminants containing carbon-carbon and/or carbon-oxygen bonds).

In one aspect a method for forming a semiconductor device structure is provided. The method involves: (a) providing a semiconductor substrate comprising an exposed layer of metal (e.g. Cu, Co, Ni) and an exposed layer of dielectric; (b) contacting the provided semiconductor substrate with a silylating agent at a first temperature to react the silylating agent with carbon-containing contaminants on the surface of the exposed metal layer; and (c) after contacting, heating the semiconductor substrate at a higher temperature to remove the reacted silylating agent from the metal surface of the semiconductor substrate. Next, after removal of the reacted silylating agent from the metal surface, the process continues by selectively depositing a capping layer on the metal surface without depositing the same capping layer on the dielectric layer. After the capping layers are selectively formed over metal lines, a dielectric diffusion barrier layer (e.g., doped or undoped silicon carbide or silicon nitride) is deposited over both the capped metal layer and the exposed dielectric layer.

Provided method is particularly well-suited for deposition of metal-containing capping layers, such as cobalt capping layers and manganese capping layers. In some embodiments, the capping layer is formed by contacting the treated substrate with an organometallic compound. For example, the substrate may be contacted with an organocobalt compound comprising cobalt and a ligand selected from the group consisting of allyl, amidinate, diazadienyl, and cyclopentadienyl. Examples of suitable organocobalt compounds for selective deposition of cobalt-containing capping layers include but are not limited to: cobalt carbonyl tert-butyl acetylene, cobaltacene, cyclopentadienyl dicarbonyl cobalt (II), cobalt amidinates, cobalt diazadienyls, and combinations thereof.

In some embodiments, provided method further includes pre-treating the substrate prior to contacting the substrate with the silylating agent to condition the surface of the substrate. Pre-treatment can be performed to render the dielectric surface more inert towards deposition of the capping material and/or to remove metal oxide (e.g., copper oxide) from the surface of the metal. Pre-treatment can be performed by one or more of direct plasma treatment, remote plasma treatment, UV treatment and thermal treatment in a gas comprising at least one of Ar, He, N₂, NH₃ and H₂. In order to avoid re-contamination of the substrate, the substrate is not exposed to ambient atmosphere after the pre-clean and before contact with the silylating agent.

The treatment with the silylating agent is performed preferably at a temperature of between about 100 and about 300° C. and at a pressure of between about 0.5 to 20 Torr. An inert gas, such as argon and/or helium can be provided with the flow of the silylating agent. In some embodiments the flow rate of the inert gas is at least about 10 times greater than the flow rate of the silylating agent. Examples of suitable silylating agents include trimethoxysilane, diethoxymethylsilane, dimethylaminotrimethylsilane, ethoxytrimethylsilane, bis-dimethylaminodimethylsilane, vinyltrimethylsilane, vinyltrimethoxysilane, trimethylsilylacetylene, (3-mercaptopropyl)trimethoxysilane, phenyltrimethoxysilane and combinations thereof.

After treatment with the silylating agent is concluded and the flow of the silylating agent is stopped, the substrate is heated to drive off the reacted silylating agent from the surface of the metal. In some embodiments, the heating is performed at a temperature of between about 120 and about 450° C. in a gas selected from the group consisting of Ar, He, N₂, NH₃, H₂ and mixtures thereof.

In some embodiments, the dielectric layer may also react with the silylating agent during treatment with the silylating agent. In some embodiments, the dielectric, when reacted with the silylating agent becomes passivated against deposition of the capping material, thereby increasing the selectivity of the capping deposition process.

In some embodiments provided methods are integrated into the processing scheme that includes photolithographic patterning and further includes: applying photoresist to the substrate; exposing the photoresist to light; patterning the photoresist and transferring the pattern to the substrate; and selectively removing the photoresist from the substrate.

In another aspect, an apparatus for forming a semiconductor device structure on a wafer substrate is provided. The apparatus includes a process chamber having an inlet for introduction of gaseous or volatile reactants; a wafer substrate support for holding the wafer substrate in position during processing of the wafer substrate in the process chamber; and a controller comprising program instructions for performing the methods provided herein. For example, the controller may include program instructions for (i) contacting a wafer substrate having an exposed layer of dielectric and an exposed layer of metal, wherein the metal is selected from the group consisting of copper, cobalt, and nickel, with a silylating agent at a first temperature to react the silylating agent with carbon-containing contaminants on the surface of the exposed metal layer; (ii) after contacting, heating the wafer substrate at a higher temperature to remove the reacted silylating agent from the metal surface of the wafer substrate; and (iii) after removal of the reacted silylating agent from the metal surface, selectively depositing a capping layer on the metal surface without depositing the same capping layer on the dielectric layer.

In some embodiments, a system is provided, wherein the system includes the apparatus described herein and a stepper.

In another aspect, a non-transitory computer machine-readable medium is provided, where the medium includes program instructions for a deposition apparatus containing code for performing any of the operations of the methods described herein.

### BRIEF DESCRIPTION OF THE DRAWINGS

FIGS. 1A-1D show schematic cross sectional depictions of device structures created during a selective capping process according to some embodiments provided herein.

FIG. 2 presents a process flow diagram of a capping process according to some embodiments presented herein.

FIG. 3 presents a schematic view of a process chamber suitable for removing carbon-based contaminants according to embodiments provided herein.

FIG. 4A is an X-ray photoelectron spectroscopic (XPS) graph illustrating carbon presence on a copper surface of electrodeposited copper layer planarized by chemical mechanical polishing (CMP).

FIG. 4B is an XPS graph illustrating carbon presence on a copper surface of a copper layer deposited by physical vapor deposition (PVD).

FIG. 5 is a plot illustrating carbon and silicon content on a copper surface after treatments with a silylating agent.

FIG. 6 is a table illustrating composition of substrate surface for samples treated under different conditions.

FIG. 7A is a bar graph illustrating cobalt deposition on dielectric and copper after treatments under different conditions.

FIG. 7B is a bar graph illustrating cobalt deposition on dielectric and copper after treatments under different conditions.

### DETAILED DESCRIPTION OF A PREFERRED EMBODIMENT

Methods and apparatuses for removing carbon-containing contaminants from metal surfaces on semiconductor substrates are provided. The contaminants are removed by treating the metal surface with a silylating agent. Provided methods can be used to clean copper, cobalt and nickel surfaces and to prepare these surfaces for CVD and ALD deposition of capping layers.

The terms “semiconductor substrate” and “partially fabricated semiconductor device” are used interchangeably and include substrates that contain semiconductor material anywhere within the substrate. It is understood that the semiconductor substrate typically further includes layers of metal and dielectric materials in addition to semiconductor material. One example of a suitable semiconductor substrate is a silicon wafer containing one or more metallization layers formed by a Damascene process. Methods provided herein can be used both in back-end and in front-end processing.

The terms “copper”, “cobalt” and “nickel” include both pure metals and alloys of these metals, where the concentration of copper, cobalt, nickel, or combination of these metals is at least about 70 atomic %. Examples of copper as used herein include 95-99% pure copper metal, and copper alloys, such as CuAl alloy, and CuMn alloy, containing at least 70 atomic % copper. For clarity, the methods will be subsequently illustrated using copper as an example. It is understood that cleaning of cobalt and nickel (including their alloys) can be similarly conducted.

The terms “capping layers” include layers deposited onto and/or within the upper portion of the cleaned metal layer. Examples of capping layers include cobalt or manganese layers deposited onto a copper line in Damascene processing.

The term “selective deposition” in which the capping layer is deposited on the metal surface without being deposited on the dielectric surface refers to a deposition in which thickness of the capping layer on the metal is at least 10 times greater than the thickness of the capping material on the dielectric. The terms “removal” and “cleaning” as used herein include both partial and complete removal.

Removal of carbon-containing contaminants from metal surfaces can be performed in a presence of a variety of exposed dielectrics. In some embodiments, the substrate contains an exposed layer of metal and an exposed layer of dielectric, where the dielectric is a low-k dielectric (3.2>k>2.7), ultralow k (ULK) dielectric (2.7>k>2.2), or an extreme low k (ELK) dielectric (k<2.2), where k is a dielectric constant. In some implementations used in front-end processing, the dielectric is a dense silicon oxide. Examples of suitable dielectrics include silicon oxide based dielectrics, such as carbon-doped silicon oxide materials, organic dielectrics, porous dielectrics, etc. The methods are particularly advantageous for treating metal layers in the presence of ULK and ELK dielectrics, because the methods can be performed, in some embodiments, under mild conditions without the use of plasma such as not to damage even most mechanically weak ULK and ELK dielectrics. Examples of suitable dielectrics include polymeric CVD-deposited films having Si—O—Si network with CH₃ terminations, such as Aurora®, and other CVD-deposited dielectrics such as Black Diamond. Dielectrics deposited by spin-on methods can also be used.

In some embodiments, treatment of the metal layer with a silylating agent concurrently modifies the dielectric and renders it inert towards deposition of the capping material, thereby improving selectivity of deposition of caps. For example, in some embodiments, the silylating agent may silylate the —OH groups on the dielectric layer, thereby rendering the dielectric inert towards capping precursors. Dielectrics containing —OH groups, such as Si—O—H groups may react with organometallic compounds used in the capping chemistries inadvertently leading to formation of Si—O-Metal groups, and leading to less selective capping processes. The silylating agent, in some embodiments reduces concentration of free Si—O—H groups on the surface of a dielectric, and thereby improves selectivity of cap deposition.

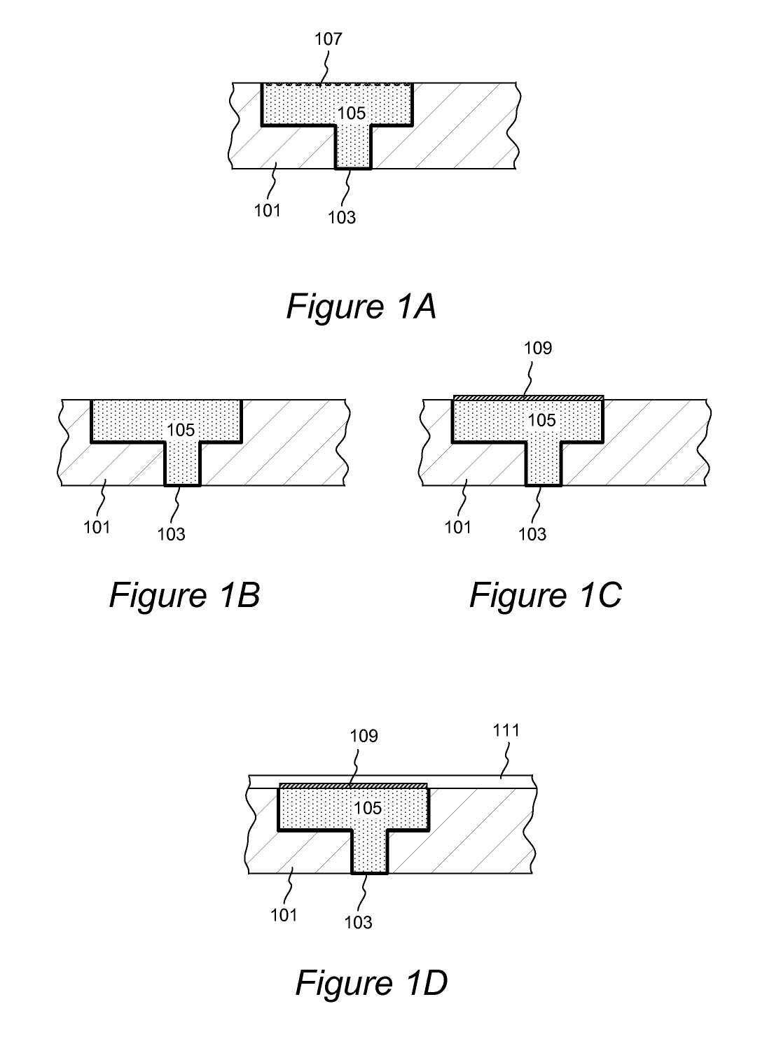

FIGS. 1A-1D illustrate partially fabricated semiconductor device structures obtained in the course of a process in accordance with an embodiment provided herein. Only the top metallization layer is shown to preserve clarity. The process starts with a structure illustrated in FIG. 1A (a Damascene structure), which contains a layer of dielectric 101 (e.g., a ULK dielectric) having an embedded copper line 105, wherein the copper line 105 is separated from the dielectric by a thin layer of diffusion barrier 103 (e.g., Ta, TaN, or a Ta/TaN bilayer). The surface of the structure contains a layer of copper, which is contaminated with carbon-containing contaminants 107 that may include contaminants containing carbon-carbon and carbon-oxygen bonds. The substrate provided in FIG. 1A is obtained after excess of copper and of diffusion barrier layer material were removed from the field region of the substrate by a chemical mechanical polishing (CMP) process. It is noted however that contamination with carbon-containing species is found not only on copper samples analyzed after CMP, but can be present even when the substrate was not subjected to CMP. For example, carbon contaminants were found on copper layers deposited by physical vapor deposition (PVD), where copper was not planarized by CMP.

Next, the substrate is optionally pre-treated, e.g. to remove copper oxide on the surface of copper or to condition the surface of dielectric 101, and then is treated with the silylating agent such that the silylating agent reacts with the carbon-containing contaminants. The substrate is then heated to remove the reacted silylating agent from the copper surface, providing a structure with clean copper surface, as shown in FIG. 1B.

Next, a capping layer, such as a cobalt capping layer 109 is selectively deposited onto the copper layer 105 without being deposited onto the dielectric 101. The deposition can be performed by contacting the substrate with an organocobalt precursor and a reducing agent. In some embodiments, between about 1-300 Å of the capping material, such as between about 10-300 Å of the capping material is deposited on the copper line. In other embodiments, the deposited cobalt is deposited within the top portion of copper line, and does not provide any additional thickness over the copper layer. In some embodiments, the cobalt is deposited both on and within copper layer.

Next, a dielectric diffusion barrier or an etch stop layer, such as doped or undoped silicon nitride and/or doped or undoped silicon carbide (e.g., SiCN) is deposited over the entire surface of the substrate. The resulting structure 1D illustrates a SiCN diffusion barrier layer 111 residing on top of the dielectric layer 101 and on top of the cobalt layer 109.

The methods for removing carbon-containing contaminants can be used in a variety of processing schemes as a metal surface preparation step prior to deposition of materials by methods that are sensitive to presence of contaminants, such as by CVD and ALD. For example, in some embodiments, the cleaning methods can be used in the following processing scheme. First a semiconductor substrate containing a first metallization layer and an overlying layer of ILD is provided. Next, the ILD is etched to define recessed features and to expose the top portion of copper lines of the first metallization layer. Next, the exposed copper lines are optionally pre-treated and are contacted with the silylating agent to react silylating agent with the carbon-containing contaminants on copper surface. The substrate is then heated to remove the reacted silylating agent from the copper surface, and then a cap (e.g., a cobalt cap) is selectively deposited on the cleaned copper layer. Next, the recessed feature having the capped copper at the bottom can be filled with a metal, e.g., by electrodeposited copper.

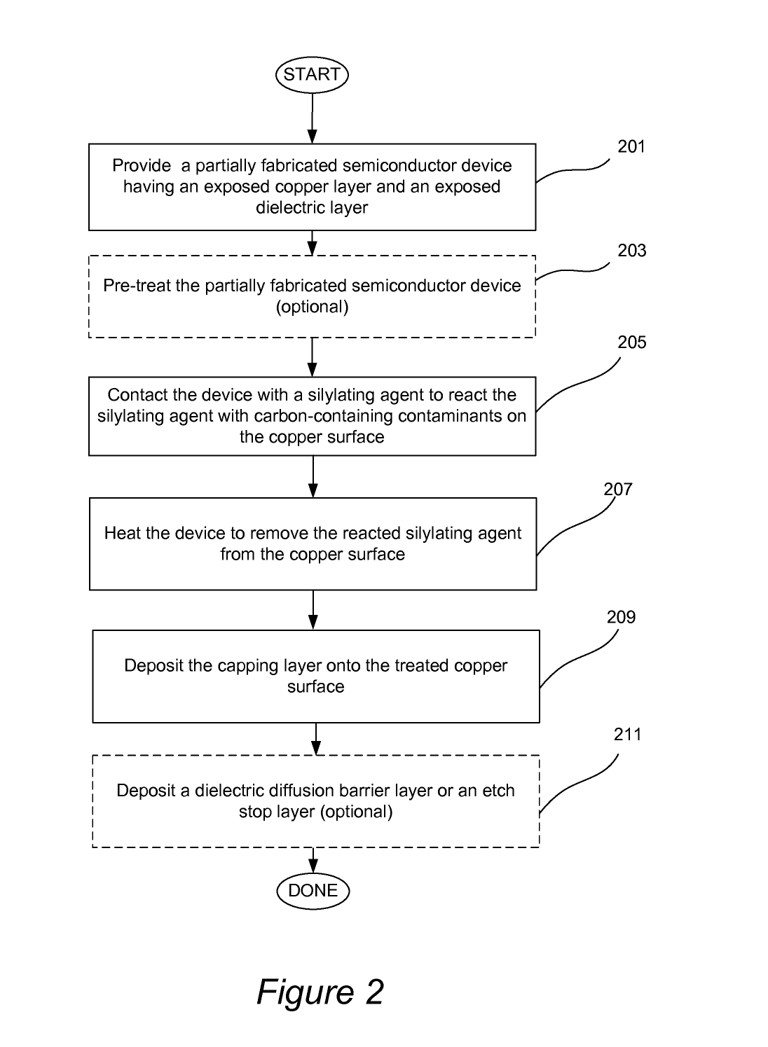

FIG. 2 provides an example of a process flow diagram for a method of selectively depositing a capping layer on a copper layer cleaned with the silylating agent treatment. In operation 201 a partially fabricated semiconductor device having an exposed copper layer and an exposed dielectric layer is provided. The device may be similar to the structure shown in FIG. 1A. In another embodiment, the device may be a structure that includes exposed copper at the bottom of a via made in an ILD layer. Next, in the operation 203 the substrate is optionally pre-treated. Pre-treatment can be performed thermally (without the use of plasma) and, in some embodiments, may include UV irradiation. In some embodiments pre-treatment is performed using a direct or remote plasma. In the pre-treatment the substrate may be contacted with a reducing gas such as H₂ or NH₃. In some embodiments during pre-treatment the substrate is contacted with an inert gas, such as N₂, He or Ar. The pre-treatment is typically performed at a temperature of between about 100-400° C., and at a pressure of between about 0.5 to 10 Torr. When plasma is used during pre-treatment it can be applied using power of between about 100 and 6000 W. In those embodiments, when UV irradiation is used, the ultraviolet light source having a significant power emitted in the wavelength of between about 180 and 250 nm is preferred. In some embodiments, particularly those that use reducing gases, the pre-treatment is used to clean copper oxide from the surface of copper. In other embodiments, pre-treatment is performed to condition the surface of dielectric and to render the dielectric more inert towards deposition of the capping layer. For example, UV irradiation in a presence of NH₃ was shown to inhibit growth of cobalt on a dielectric.

After pre-treatment is completed, it is important not to expose the substrate to ambient atmosphere in order to avoid re-contamination of the metal surface. Therefore, without an airbreak, the substrate is contacted in operation 203 with the silylating agent to react the silylating agent with the carbon-containing contaminants on the copper surface. The treatment is performed in an absence of plasma, and preferably (but not necessarily) in the absence of UV irradiation. The treatment is preferably performed at a temperature of between about 100-300° C. and at a pressure of between about 0.5 to 20 Torr. The silylating agent is typically supplied in a gaseous form together with an inert gas, such as N₂, Ar, He, or with a mixture of any of these gases. In some embodiments the flow rate of the inert gas is at least ten times the flow rate of the silylating agent. The substrate is exposed to silylating agent, in some embodiments for 5-120 seconds. The silylating agent is an organosilicon compound. Without wishing to be bound by a specific mechanism of operation, it is believed that a suitable organosilicon compound contains one or more leaving groups (such as an alkoxy group, dialkylamino group, etc.), that are substituted upon reaction. Preferably the silylating agent does not contain halogen substituents because these may cause corrosion of metal upon leaving. The silylating agent may contain such substituents as hydrogen, alkyl, alkoxy, vinyl, amino, mercapto, phenyl, and acetylene. Suitable silylating agents include trimethoxysilane, diethoxymethylsilane, dimethylaminotrimethylsilane, ethoxytrimethylsilane, bis-dimethylaminodimethylsilane, vinyltrimethylsilane, vinyltrimethoxysilane, trimethylsilylacetylene, (3-mercaptopropyl)trimethoxysilane, phenyltrimethoxysilane. In some embodiments preferred organosilicon compounds are of the formula R¹R²₃Si, where R¹ is selected from the group consisting of secondary amino (e.g., dimethylamino), vinyl, acetyl and alkoxy (e.g., ethoxy), and wherein R² is an alkyl, such as methyl. After treatment, the substrate is heated in an operation 207 to remove the reacted silylating agent from the copper surface. It is not necessary to maintain the substrate in an inert gas atmosphere after treatment with the silylating agent. Hence, there may be an air break between operations 205 and 207. Heating can be performed at a temperature of between about 120-450° C. In some embodiments heating is performed at a temperature that is at least 50, preferably at least 100° C. greater than the temperature at which the substrate was treated with the silylating agent. For example the substrate may be treated with the silylating agent at a temperature of about 250° C., and heating can be conducted at about 400° C. Heating can be performed in an inert gas atmosphere or in a presence of a reducing gas. For example heating can be performed in a presence of one or more of N₂, Ar, He, NH₃, and H₂ at a pressure of between about 0.5-20 Torr. In an exemplary process, heating is performed for about 5 minutes at a temperature of 400° C. in the presence of argon at a pressure of about 15 Torr.

Next, after the silylating agent is removed from the copper surface, a capping layer is selectively deposited onto the copper surface in operation 209. Selectivities of greater than 20, such as greater than 40 can be achieved (where selectivity refers to a ratio of capping material thickness deposited on copper to capping material thickness deposited on dielectric). A variety of caps can be deposited onto copper layers using CVD and ALD methods. In some embodiments cobalt capping material is deposited by CVD using an organocobalt compound as a precursor. Suitable organocobalt compounds include cobalt carbonyl tert-butyl acetylene, cobaltacene, cyclopentadienyl dicarbonyl cobalt (II), cobalt amidinates, cobalt diazadienyls, containing ligand variations and combinations thereof.

It is noted that because of the cleaning procedure provided herein, some of organocobalt precursors that were not capable of selective deposition on uncleaned surface, became suitable and deposited cobalt selectively. These precursors include but are not limited to organometallic cobalt precursors containing ligands such as allyls, amidinates, cyclopentadienyls, diazadienyls, and alkoxides. The organometallic cobalt compound is typically provided in a vaporized form in a mixture with an inert gas such as argon. The substrate is contacted with the organometallic compound and a reducing agent. It was found that relatively low temperatures should preferably be used to suppress gas-phase reaction between the organometallic compound and the reducing agent that may lead to reduced deposition selectivity. For example, process temperatures of between about 60-200° C., such as between 70-100° C. can be used to effectively promote deposition of cobalt at the surface of copper, while being sufficiently low for a gas-phase reaction to be suppressed. Further, it was found that relatively low pressures are also advantageous for suppressing the gas-phase reaction between the cobalt compound and the reducing agent, while allowing surface-driven deposition onto copper. In some embodiments, the cobalt deposition is performed at a pressure of between about 0.2-200 Torr. For example, in some embodiments, deposition is performed at a pressure of about 1 Torr. Suitable reducing agents include hydrazine, hydrazine hydrate, alkyl hydrazines, 1,1-dialkylhydrazines, 1,2-dialkylhydrazines, ammonia, silanes, disilanes, trisilanes, germanes, diborane, formaldehyde, amine boranes, dialkyl zinc, alkyl aluminum compounds, alkyl gallium compounds, alkyl indium compounds and their combinations. While in a preferred embodiment cobalt deposition is performed in an absence of plasma, in alternative embodiments hydrogen plasma and/or ammonia plasma may be used. In other embodiments, a manganese capping material is deposited by CVD or ALD using by contacting the substrate with an organomanganese precursor. Suitable precursors include but are not limited to organometallic manganese precursors containing ligands such as allyls, amidinates, cyclopentadienyls, diazadienyls, and alkoxides

After the capping layer has been deposited, a diffusion barrier layer is optionally deposited over the substrate to contact both the capping layer and the dielectric. Suitable diffusion barriers include doped and undoped SiC and SiN. These layers can be deposited by PECVD. For examples, SiCN can be deposited by PECVD by forming plasma in a gas containing a precursor, containing silicon and carbon (e.g., an alkylsilane) and a nitrogen-containing gas (e.g., NH₃). Adhesion of such diffusion barrier layers to copper is substantially improved because of the presence of a capping layer on the copper line.

Apparatus

In general, cleaning of copper lines from carbon-based contaminants and formation of protective caps can be performed in any type of apparatus which allows for introduction of volatile precursors, and that is configured to provide control over reaction conditions, e.g., chamber temperature, precursor flow rates, exposure times, etc. It is often preferred to perform operations 201-211 without exposing the substrate to an ambient environment, in order to prevent inadvertent oxidation and contamination of the substrate. In one embodiment, operations 201-211 are performed sequentially in one module without breaking the vacuum. In some embodiments, operations 201-211 are performed in one module having multiple stations within one chamber, or having multiple chambers. VECTOR™ module available from Lam Research, Inc of Fremont, Calif. is an example of a suitable apparatus. In other embodiments, pre-clean and treatment with the silylating agent can be performed in one apparatus, and subsequent operations can be performed in a different apparatus with an airbreak after treatment with the silylating agent.

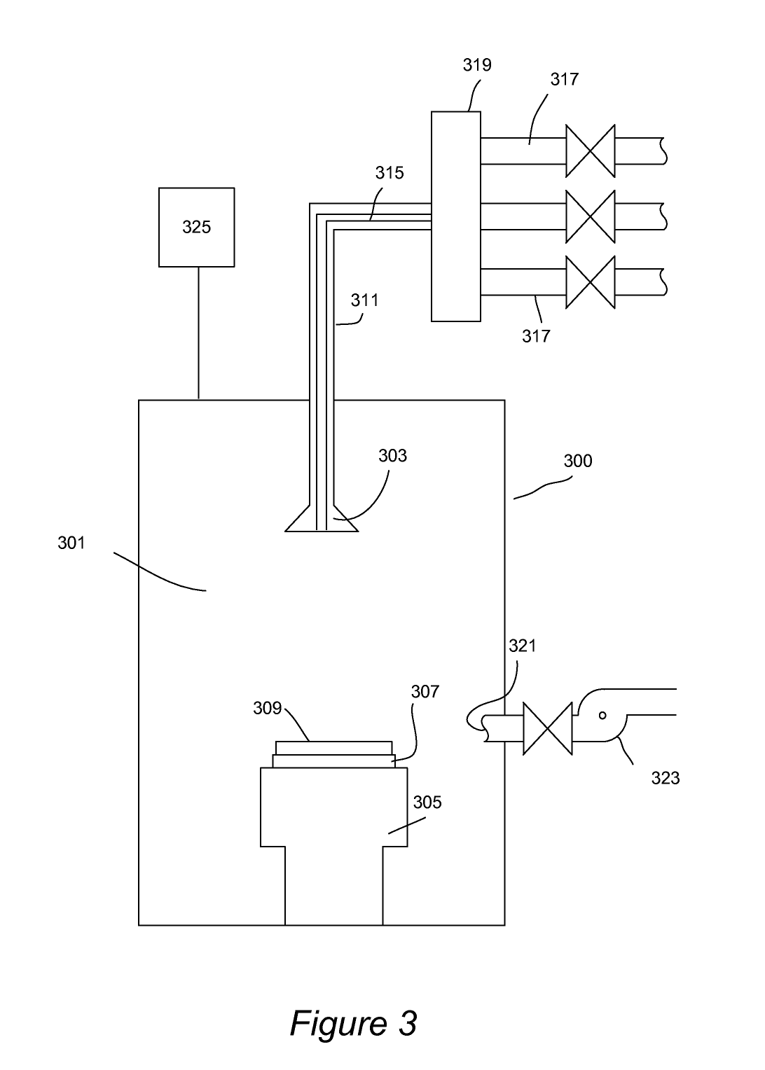

An exemplary apparatus will include one or more chambers or “reactors” (sometimes including multiple stations) that house one or more wafers and are suitable for wafer processing. Each chamber may house one or more wafers for processing. The one or more chambers maintain the wafer in a defined position or positions (with or without motion within that position, e.g. rotation, vibration, or other agitation). FIG. 3 provides a simple block diagram depicting various reactor components arranged for implementing cleaning of copper surface in accordance with embodiments provided herein. As shown, a reactor 300 includes a process chamber 301, which encloses other components of the reactor and serves to contain the process gas delivered through a showerhead 303. Within the reactor, a wafer pedestal 307 supports a wafer substrate 309 and also includes a heating block 305 for heating the substrate. The pedestal typically includes a chuck, a fork, or lift pins to hold and transfer the substrate during and between the deposition reactions. The chuck may be an electrostatic chuck, a mechanical chuck or various other types of chuck as are available for use in the industry and/or research.

The process gases are introduced via inlet 311 and are delivered by a gas line 315. Multiple source gas lines 317 are connected to manifold 319. The gases may be premixed or not. Appropriate valving and mass flow control mechanisms are employed to ensure that the correct gases are delivered during the pre-treatment, and treatment with the silylating agent. In case where the silylating agent is delivered in the liquid form, liquid flow control mechanisms are employed. The liquid is then vaporized and mixed with other process gases during its transportation in a manifold heated above its vaporization point before reaching the deposition chamber.

Process gases exit chamber 300 via an outlet 321. A vacuum pump 323 (e.g., a one or two stage mechanical dry pump and/or a turbomolecular pump) typically draws process gases out and maintains a suitably low pressure within the reactor by a close loop controlled flow restriction device, such as a throttle valve or a pendulum valve.

A controller 325 is electrically connected with the apparatus and is configured for controlling the pre-treatment and cleaning processes. The controller may include program instructions for providing necessary temperature, pressure, flows of precursors and other processing parameters of the provided methods.

In those embodiments, where pre-treatment, or silylating agent treatment are performed with UV irradiation, the apparatus further includes a UV lamp (not shown) configured to irradiate the substrate with UV light and connected with the controller. In those embodiments, where pre-treatment is performed with plasma, the apparatus may further include a plasma generator for high frequency (HF) and/or low frequency (LF) plasma, connected with the controller. In some embodiments, the apparatus is configured for use of remote plasma during the pre-treatment and includes a plasma generation chamber in fluid communication with the process chamber, where the apparatus is configured for delivering radicals from the plasma generation chamber to the process chamber during the pre-treatment.

Another aspect of the invention is system or a module configured to accomplish the methods described herein. A suitable system includes hardware for accomplishing the process operations and a system controller having instructions for controlling process operations in accordance with the present invention. The system controller will typically include one or more memory devices and one or more processors configured to execute the instructions so that the apparatus will perform a method in accordance with the present invention. Machine-readable media containing instructions for controlling process operations in accordance with the present invention may be coupled to the system controller. For example, the controller may include program instructions or built-in logic for providing suitable process conditions for substrate pre-treatment, silylating agent treatment, and capping layer deposition. For example, the controller can include program instructions for maintaining suitable temperature during silylating agent treatment, and raising the temperature to remove the silylating agent. The controller may also control the UV lamp during pre-treatment and may include program instructions for the UV irradiation of the substrate. In general, the controller may include instructions to perform any of the steps of the methods provided herein.

The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### EXPERIMENTAL EXAMPLES

### Example 1

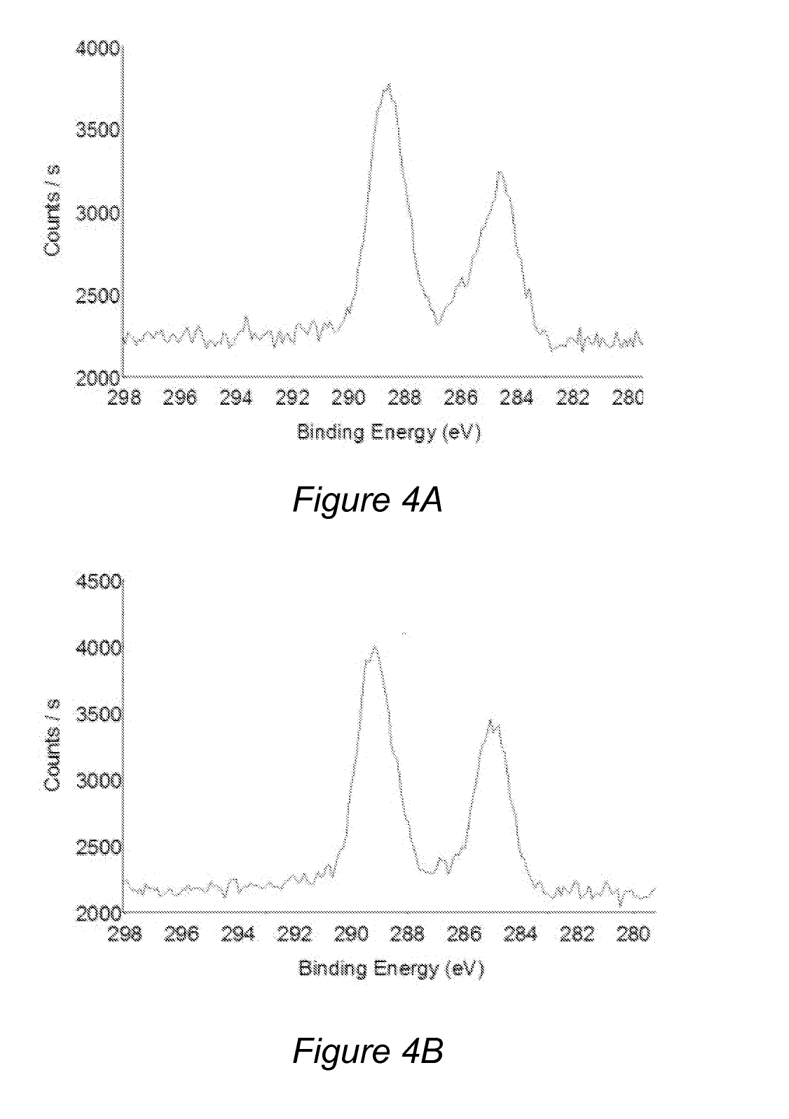

X-Ray Photoelectron spectroscopic (XPS) data was obtained on thin copper films deposited and processed by different methods. FIG. 4A shows XPS data for a thin copper film deposited by electroplating and planarized by CMP. Two peaks assigned to carbon-containing contaminants were observed in this sample: a peak at about 289 eV is assigned to a carbon-oxygen (carbonate) bonding and a peak at about 285 eV assigned to C—C or C—H bonding. FIG. 4B shows XPS data for a thin copper film deposited by PVD that was not subjected to subsequent CMP treatment. Two peaks assigned to carbon-containing contaminants were also observed in this sample: a peak at about 289 eV is assigned to a carbon-oxygen (carbonyl) bonding and a peak at about 285 eV assigned to C—C or C—H bonding. Both graphs refer to C1s XPS data. These data illustrate that carbon-containing contaminants are present on copper layer deposited by different methods, and are not limited to contamination derived from chemical compositions used in CMP.

### Example 2

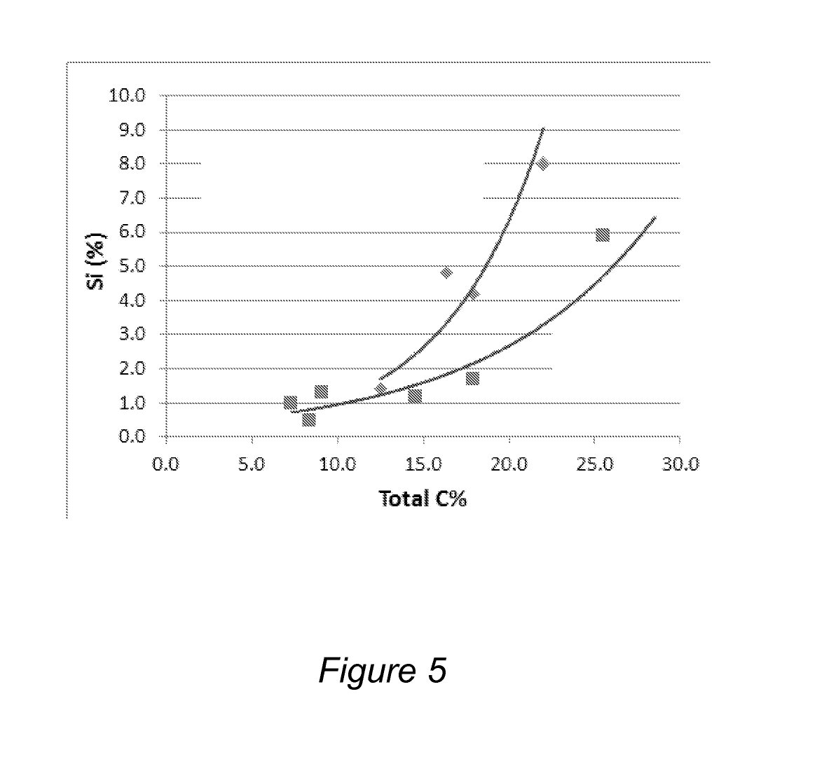

Carbon and silicon content was measured by XPS (using integrated areas of C1s and Si2p peaks respectively) in different samples of copper layers treated with a silylating agent under different conditions. Graph shown in FIG. 5 illustrates dependence of silicon content (y-axis) on total carbon content (x-axis). Two series of data were obtained. The series shown in diamonds refers to the samples of electrodeposited CMP-treated copper. The series shown in squares refers to the samples of PVD-deposited copper that was not planarized by CMP. It can be seen that in both series the carbon and silicon content are positively correlated, suggesting a binding between the carbon-containing contaminants and the silylation agent.

### Example 3

XPS data for carbon (C1s) were obtained on a sample containing a copper layer before and after treatment with a silylating agent, where the treatment included heating to remove the reacted silylating agent. The intensity of peaks at about 285 eV and 289 eV was substantially reduced.

### Example 4

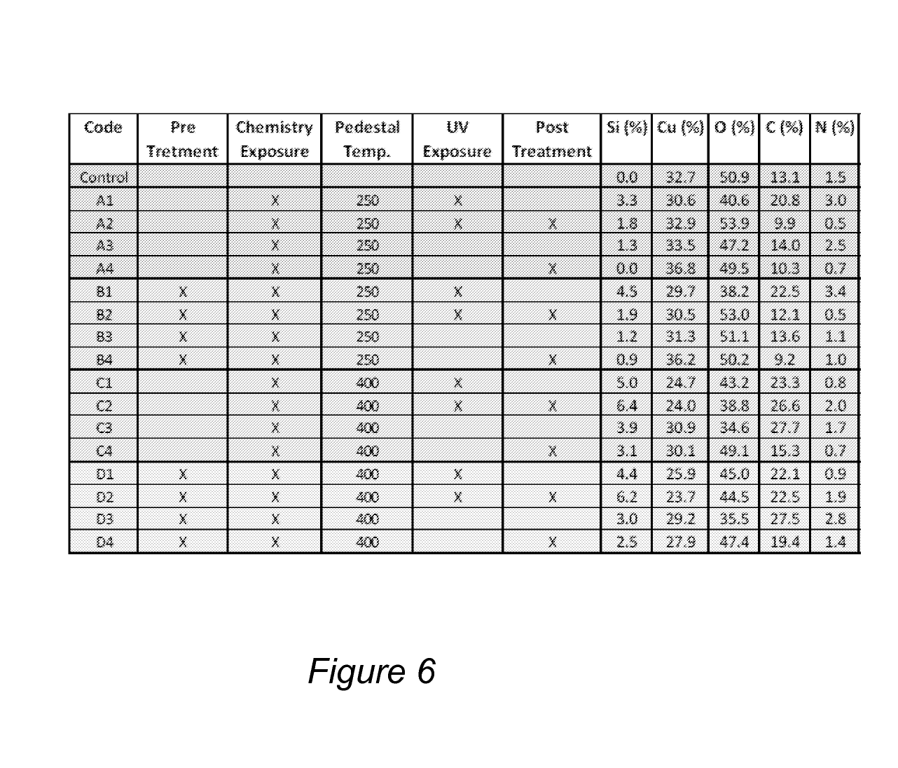

Silicon, copper, oxygen, carbon, and nitrogen content on copper surface was measured on electrodeposited CMP-treated copper layers by XPS after the layers were treated under different conditions. The results are shown in a table provided in FIG. 6. The first column of the table lists a sample identification number. The second column of the table indicates whether a particular sample was pre-treated. Pre-treatment was performed by subjecting that substrate to a UV irradiation (at 90% of UV lamp intensity) in NH₃ gas at a pressure of 15 Torr for 30 seconds. The third column of the table refers to the exposure to the silylating agent (chemistry exposure). The samples were exposed to dimethylaminotrimethylsilane silylating agent for 60 seconds without the use of plasma. The fourth column lists process temperature (pedestal temperature) at which the treatment with the silylating agent was performed. Samples A1-A4 were treated at 250° C. and samples B1-B4 were treated at 400° C. The fifth column lists UV exposure that was performed on samples A1, A2, B1, B2, C1, and C2 during treatment with the silylating agent. The sixth column lists post-treatment which was performed on samples A2, A4, B2, B4, C2 and C4 by heating the samples at 400° C. at a pressure of 15 Torr in argon atmosphere for 5 minutes. The remaining columns list content of silicon, copper, oxygen, carbon, and nitrogen (in atomic %). The “control” sample lists the content of these elements on a surface of copper in the absence of any treatments. It can be seen that the content of carbon on copper surface is reduced (compared to control) in samples A2, A4, B2, and B4, which were treated with the silylating agent at a temperature of 250° C. and were then heated at a higher temperature to remove the reacted silylating agent. Samples A4 and B4 that were treated in the absence of UV irradiation showed lower content of silicon on their surface than samples A2 and B2 treated in the presence of UV irradiation.

### Example 5

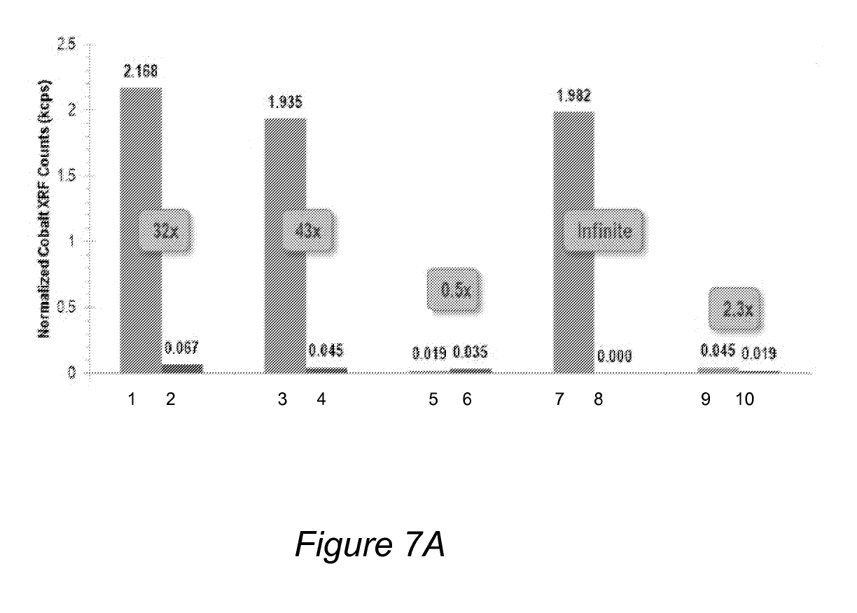

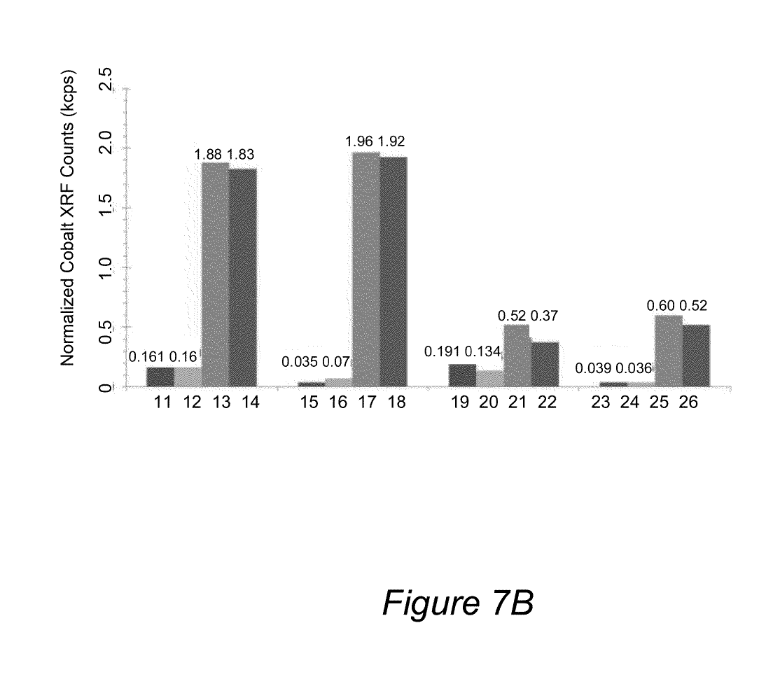

Cobalt was deposited by MOCVD on copper layer and on ULK dielectric (k=2.55). Cobalt content was measured on copper and ULK dielectric surfaces and selectivity of deposition was determined as a ratio of cobalt concentration on copper to cobalt concentration on dielectric. FIG. 7A shows a bar graph illustrating cobalt content on copper samples and ULK dielectric samples for different deposition conditions.

For all samples cobalt was deposited by exposing substrate to a carbonyl-based cobalt precursor in the process gas containing hydrogen gas in an absence of plasma. Samples 1 and 2 illustrate cobalt concentration on copper and dielectric (respectively) on substrates that were not treated with the silylating agent. A selectivity of 32 was obtained. Samples 3 and 4 illustrate cobalt concentration on copper and dielectric (respectively) on substrates that were treated with the silylating agent at 250° C. and then heated at 400° C. to remove the reacted silylating agent. It can be seen that selectivity is improved to 43. Samples 5 and 6 illustrate cobalt concentration on copper and dielectric (respectively) on substrates that were treated with the silylating agent at 250° C. without subsequent heating and removal of the reacted silylating agent. It can be seen that cobalt growth on copper is inhibited in this case. Samples 7 and 8 illustrate cobalt concentration on copper and dielectric (respectively) on substrates that were pre-treated with NH₃ at 250° C. concurrently with UV irradiation, then treated with the silylating agent at 250° C. and subsequently heated to remove the reacted silylating agent. It can be seen that selectivity is greatly enhanced in this case, and that no deposition of cobalt on the dielectric was detected. Samples 9 and 10 illustrate cobalt concentration on copper and dielectric (respectively) on substrates that were pre-treated with NH₃ at 250° C. concurrently with UV irradiation, then treated with the silylating agent at 250° C. and without subsequent heating to remove the reacted silylating agent. It can be seen that growth of cobalt on copper is inhibited in this case, leading to poor deposition selectivity.

### Example 6

Cobalt was deposited by MOCVD on different types of copper layers and on different ULK dielectrics. Cobalt content was measured by XRF and is shown in a bar graph presented in FIG. 7B. Specifically samples 11, 15, 19, and 23 show deposition on ULK (k=2.4); samples 12, 16, 20, and 24 show deposition on ULK (k=2.55), samples 13, 17, 21, and 25 show deposition on PVD-deposited copper, and samples 14, 18, 22, and 26 show deposition on electrodeposited copper planarized by CMP. Cobalt was deposited using the same method as described in Example 5. All samples were treated with a silylating agent and were then subjected to heating at 400° C. in argon atmosphere to remove the reacted silylating agent. Samples 11, 12, 13, 14 were treated with the silylating agent at 250° C. in the absence of UV irradiation and without any pre-treatment. Samples 15, 16, 17, 18 were pre-treated with ammonia at 250° C. concurrently with UV irradiation, and were then treated with the silylating agent at 250° C. Samples 19, 20, 21, and 22 were treated with the silylating agent at 400° C. in the absence of UV irradiation and without any pre-treatment. Samples 23, 24, 25, and 26 were pre-treated with ammonia at 250° C. concurrently with UV irradiation, and were then treated with the silylating agent at 400° C. It can be seen that lower temperature (250° C.) is more preferable during treatment with the silylating agent than higher temperature (400° C.) and that UV pre-treatment with ammonia reduced growth of cobalt on the dielectric in all tested samples.

What is claimed is:

1. A method for forming a semiconductor device structure, the method comprising:
(a) providing a semiconductor substrate comprising an exposed layer of metal and an exposed layer of dielectric, wherein the metal is selected from the group consisting of copper, cobalt, and nickel;
(b) contacting the provided semiconductor substrate with a silylating agent at a first temperature to react the silylating agent with carbon-containing contaminants on the surface of the exposed metal layer; and
(c) after contacting, heating the semiconductor substrate at a higher temperature to remove the reacted silylating agent from the metal surface of the semiconductor substrate; and
(d) after removal of the reacted silylating agent from the metal surface, selectively depositing a capping layer on the metal surface without depositing the same capping layer on the dielectric layer.

2. The method of claim 1, wherein the exposed layer of metal is an exposed layer of copper.

3. The method of claim 1, wherein the capping layer is a metal-containing capping layer.

4. The method of claim 1, wherein the capping layer is a metal-containing capping layer comprising cobalt and/or manganese.

5. The method of claim 1, wherein (d) comprises contacting the substrate with an organometallic compound.

6. The method of claim 1, wherein (d) comprises contacting the substrate with an organocobalt compound comprising cobalt and a ligand selected from the group consisting of allyl, amidinate, diazadienyl, and cyclopentadienyl.

7. The method of claim 1, further comprising pre-treating the substrate prior to contacting the substrate with the silylating agent, wherein the pre-treatment is selected from the group consisting of direct plasma treatment, remote plasma treatment, UV treatment and thermal treatment in a gas comprising at least one of Ar, He, N₂, NH₃ and H₂.

8. The method of claim 7, wherein the substrate is not exposed to atmosphere between pre-treating and contact with the silylating agent.

9. The method of claim 1, wherein the silylating agent is selected from the group consisting of trimethoxysilane, diethoxymethylsilane, dimethylaminotrimethylsilane, ethoxytrimethylsilane, bis-dimethylaminodimethylsilane, vinyltrimethylsilane, vinyltrimethoxysilane, trimethylsilylacetylene, (3-mercaptopropyl)trimethoxysilane, phenyltrimethoxysilane and combinations thereof.

10. The method of claim 1, wherein the first temperature is between about 100 and about 300° C.

11. The method of claim 1, wherein the silylating agent is provided with an inert gas, and wherein the flow rate of the inert gas is at least about 10 times greater than the flow rate of the silylating agent.

12. The method of claim 1, wherein (b) is performed at a pressure of between about 0.5 to 20 Torr.

13. The method of claim 1, wherein (c) is performed at a temperature of between about 120 and about 450° C. in a gas selected from the group consisting of Ar, He, N₂, NH₃, H₂ and mixtures thereof.

14. The method of claim 1, wherein the silylating agent further reacts with the exposed dielectric and passivates the dielectric towards deposition of the capping layer.

15. The method of claim 1, wherein the dielectric has a dielectric constant of less than about 3.

16. The method of claim 1, further comprising:
(e) depositing a dielectric layer over the capped metal and over the exposed dielectric.

17. The method of claim 16, wherein the dielectric layer comprises doped or undoped silicon carbide.

18. The method of claim 1, further comprising:
applying photoresist to the substrate;
exposing the photoresist to light;
patterning the photoresist and transferring the pattern to the substrate;
and selectively removing the photoresist from the substrate.

19. An apparatus for forming a semiconductor device structure on a wafer substrate, the apparatus comprising:
(a) a process chamber having an inlet for introduction of gaseous or volatile reactants;
(b) a wafer substrate support for holding the wafer substrate in position during processing of the wafer substrate in the process chamber; and
(c) a controller comprising program instructions for:
(i) contacting the wafer substrate having an exposed layer of dielectric and an exposed layer of metal, wherein the metal is selected from the group consisting of copper, cobalt, and nickel, with a silylating agent at a first temperature to react the silylating agent with carbon-containing contaminants on the surface of the exposed metal layer; and
(ii) after contacting, heating the wafer substrate at a higher temperature to remove the reacted silylating agent from the metal surface of the wafer substrate; and
(iii) after removal of the reacted silylating agent from the metal surface, selectively depositing a capping layer on the metal surface without depositing the same capping layer on the dielectric layer.

20. A system comprising an apparatus of claim 19 and a stepper.
